(19) United States
(12) Patent Application Publication
(10) Pub. No.: US 2026/0206247 A1
(43) Pub. Date: Jul. 16, 2026

(54) FIELD EFFECT TRANSISTOR

(71) Applicant: Northrop Grumman Systems Corporation, Falls Church, VA (US)

(72) Inventors: Robert S. Howell, Silver Spring, MD (US); Jizhong Li, Bordentown, NJ (US); Justin A. Parke, Ellicott City, MD (US); Shamima Afroz, Ellicott City, MD (US)

(21) Appl. No.: 19/021,483

(22) Filed: Jan. 15, 2025

(51) Int. Cl. H10D 30/47; H10D 30/01; H10D 62/85; H10D 64/23; H10D 64/64

(52) U.S. Cl. CPC H10D 30/4732; H10D 30/015; H10D 62/8503; H10D 64/251; H10D 64/64

(57) ABSTRACT

A field effect transistor may include a base structure. A first heterostructure may have a first layer located over the base structure, a second layer located over the first layer, and a first 2DxG channel. A second heterostructure may have a third layer located in contact with the second layer, a fourth layer located over the third layer, and a second 2DxG channel. A source electrode and a drain electrode may each be connected to each of the 2DxG channels. A plurality of trenches may be located between the source electrode and the drain electrode, each of the plurality of trenches defining a boundary. A gate electrode located over the fourth layer, the gate electrode located within each of the plurality of trenches. A semiconductor barrier layer is grown along at least a portion of the boundary of the trench between the gate electrode and the first and second heterostructures.

### FIELD

The present disclosure generally relates to a heterostructure Field-Effect Transistor (“FET”). More particularly, the present disclosure is directed to a heterostructure FET having a superlattice structure with a one or more Two-Dimensional Electron Gas (2DEG) channels.

### BACKGROUND

An RF switch may be designed to minimize the on-resistance, Rₒₙ, while also minimizing the off-capacitance, C_{off}. The RF switch, when “on”, passes a signal without attenuation, distortion, or insertion loss (all of which being a function of on-resistance) and, when “off”, isolates the signal and prevents it from leaking through the switch (leakage being a function of the off-capacitance). In order to be able to use an RF switch in various applications, the RF switch may be configured to have a large bandwidth, which is proportional to the Figure of Merit for RF switches, the RF switch cut-off frequency.

In some FET designs, lowering the on-resistance, such as by increasing the periphery of the transistor, generally causes the off-capacitance to increase proportionately. Given the inversely-proportional relationship between on-resistance and off-capacitance, it is difficult to improve (e.g., lower) insertion loss while not adversely impacting (e.g., lowering) the isolation simultaneously.

Accordingly, an improved field-effect transistor would be welcomed in this technology domain.

### SUMMARY

Aspects and advantages of the technology will be set forth in part in the following description, or may be obvious from the description, or may be learned through practice of the technology.

In one embodiment, the present disclosure is directed to a field effect transistor that includes a base structure. A first heterostructure has a first layer located over the base structure, a second layer located over the first layer, and a first 2DxG channel located near an interface between the first layer and the second layer. A second heterostructure has a third layer located in direct contact with the second layer, a fourth layer located over the third layer, and a second 2DxG channel located near an interface between the third layer and the fourth layer. A source electrode is located over the fourth layer and is ohmically connected to each of the first 2DxG channel and the second 2DxG channel. A drain electrode is located over the fourth layer and is ohmically connected to each of the first 2DxG channel and the second 2DxG channel. A plurality of trenches is located between the source electrode and the drain electrode. Each of the plurality of trenches has a length, a width, and a depth defining a boundary including a first sidewall surface, a second sidewall surface, and a bottom section located therebetween. The bottom section of each of the plurality of trenches is at or below the first 2DxG channel. A gate electrode is located over the fourth layer. The gate electrode is located within each of the plurality of trenches. A semiconductor barrier layer is grown along at least a portion of the boundary of the plurality of trenches between the gate electrode and the first heterostructure and the second heterostructure.

In one embodiment, the present disclosure is directed to a method of forming a transistor. The method includes forming a substrate having a superlattice structure and a base structure in an epitaxial growth chamber. The superlattice structure includes a plurality of heterostructures over a base structure by sequentially depositing each layer of the plurality of heterostructures over the base structure with one layer of each heterostructure being doped. The method also includes etching away openings in the superlattice structure over a channel region to form a castellated region in the channel region defining a plurality of trenches. The method further includes reintroducing the substrate in the epitaxial growth chamber to grow a semiconductor barrier layer on at least a portion of a boundary of the plurality of trenches. Lastly, the method includes performing a gate fill process to form a gate that wraps around and substantially surrounds a top and sides of each of the plurality of heterostructures along at least a portion of its depth and connects each one of the plurality of heterostructures through non-channel openings.

In one embodiment, the present disclosure is directed to a field effect transistor that includes a base structure. A plurality of heterostructures is positioned on the base structure, the plurality of heterostructures each including a 2DxG channel. A source electrode is located over the plurality of heterostructures and is ohmically connected to each of the 2DxG channels. A drain electrode is located over the plurality of heterostructures and is ohmically connected to each of the 2DxG channels. A plurality of trenches is located between the source electrode and the drain electrode. Each of the plurality of trenches defines a boundary including a first sidewall surface, a second sidewall surface, and a bottom section located therebetween. A gate electrode is located over the field effect transistor. The gate electrode is located within at least one of the plurality of trenches. A semiconductor barrier layer is grown along at least a portion of the boundary of the plurality of trenches.

These and other features, aspects, and advantages of the present technology will become better understood with reference to the following description and appended claims. The accompanying drawings, which are incorporated in and constitute a part of this specification, illustrate embodiments of the technology and, together with the description, serve to explain the principles of the technology.

### BRIEF DESCRIPTION OF THE DRAWINGS

A full and enabling disclosure of the present technology directed to one of ordinary skill in the art, is set forth in the specification, which makes reference to the appended figures, in which:

FIG. 1 is a side view of an epitaxial structure in accordance with various aspects of the present disclosure;

FIG. 2 is a top view of a field effect transistor in accordance with various aspects of the present disclosure;

FIG. 3 is an orthogonal view of one of the channels shown in FIG. 2 in accordance with various aspects of the present disclosure;

FIG. 4 is a top view of a field effect transistor in accordance with various aspects of the present disclosure;

FIG. 5 is a cross-sectional view of the field effect transistor taken along the line V-V of FIG. 4;

FIG. 6 is a cross-sectional view of the field effect transistor taken along the line VI-VI of FIG. 4;

FIG. 7 is a cross-sectional view of the field effect transistor taken along the line VII-VII of FIG. 4;

FIG. 8 is a cross-sectional view of the field effect transistor taken along the line VIII-VIII of FIG. 4; and

FIG. 9 is a flow diagram for forming a transistor in accordance with various aspects of the present disclosure.

Repeat use of reference characters in the present specification and drawings is intended to represent the same or analogous features or elements of the present technology.

### DETAILED DESCRIPTION

Reference now will be made in detail to embodiments of the disclosure, one or more examples of which are illustrated in the drawings. Each example is provided by way of explanation of the discourse, not limitation of the disclosure. In fact, it will be apparent to those skilled in the art that various modifications and variations may be made in the present disclosure without departing from the scope or spirit of the disclosure. For instance, features illustrated or described as part may be used with another embodiment to yield a still further embodiment. Thus, it is intended that the present disclosure covers such modifications and variations as come within the scope of the appended claims and their equivalents.

In this document, relational terms, such as first and second, top and bottom, and the like, are used solely to distinguish one entity or action from another entity or action, without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

As used herein, the terms “first,” “second,” and “third” may be used interchangeably to distinguish one component from another and are not intended to signify a location or importance of the individual components. The terms “coupled,” “fixed,” “attached to,” and the like refer to both direct coupling, fixing, or attaching, as well as indirect coupling, fixing, or attaching through one or more intermediate components or features, unless otherwise specified herein. The term “selectively” refers to a component's ability to operate in various states (e.g., an ON state and an OFF state) based on manual and/or automatic control of the component.

Furthermore, any arrangement of components to achieve the same functionality is effectively “associated” such that the functionality is achieved. Hence, any two components herein combined to achieve a particular functionality may be seen as “associated with” each other such that the desired functionality is achieved, irrespective of architectures or intermedial components. Likewise, any two components so associated may also be viewed as being “operably connected” or “operably coupled” to each other to achieve the desired functionality, and any two components capable of being so associated may also be viewed as being “operably couplable” to each other to achieve the desired functionality. Some examples of operably couplable include, but are not limited to, physically mateable, physically interacting components, wirelessly interactable, wirelessly interacting components, logically interacting, and/or logically interactable components.

The singular forms “a,” “an,” and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about,” “approximately,” “generally,” and “substantially,” is not to be limited to the precise value specified. In at least some instances, the approximating language may correspond to the precision of an instrument for measuring the value, or the precision of the methods or apparatus for constructing or manufacturing the components and/or systems. For example, the approximating language may refer to being within a ten percent margin.

Moreover, the technology of the present application will be described in relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

As used herein, the term “and/or,” when used in a list of two or more items, means that any one of the listed items may be employed by itself, or any combination of two or more of the listed items may be employed. For example, if a composition or assembly is described as containing components A, B, and/or C, the composition or assembly may contain A alone; B alone; C alone; A and B in combination; A and C in combination; B and C in combination; or A, B, and C in combination.

In general, the present disclosure is directed to a heterostructure Field-Effect Transistor (“FET”) that may have a superlattice structure with a plurality of Two-Dimensional Electron Gas (2DEG) channels, all of which are capable of being turned “off” by the application of a relatively low gate voltage. The present disclosure may be equally applicable to superlattice structures having a plurality of Two-Dimensional Hole Gas (2DHG) channels.

For instance, the field effect transistor may include a base structure. A first heterostructure may have a first layer located over the base structure, a second layer located over the first layer, and a first 2DxG channel located near the interface between the first layer and the second layer. A second heterostructure may have a third layer located in direct contact with the second layer, a fourth layer located over the third layer, and a second 2DxG channel located near the interface between the third layer and the fourth layer. A source electrode may be located over the fourth layer and ohmically connected to each of the 2DxG channels. A drain electrode may be located over the fourth layer and ohmically connected to each of the 2DxG channels. A plurality of trenches may be located between the source electrode and the drain electrode. Each of the trenches may have a length, a width, and a depth defining a boundary including a first sidewall surface, a second sidewall surface, and a bottom section located therebetween. The bottom section of each of the trenches may be at or below the first 2DxG channel. A gate electrode may be located over the fourth layer. In addition, the gate electrode may be located within each of the trenches. A semiconductor barrier layer may be grown along at least a portion of the boundary of the trench.

In conventional FET designs, any attempt to lower the on-resistance, such as by increasing the periphery of the transistor, generally causes the off-capacitance to increase proportionately. Given the inversely-proportional relationship between on-resistance and off-capacitance, it is difficult to improve (e.g., lower) insertion loss while not adversely impacting (e.g., lowering) the isolation simultaneously. Some FETs have attempted to reduce on-resistance by fabricating, in a laboratory setting, heterostructure FETs having a plurality of 2DEG channels. The term “heterostructure” (also, “hetero-junction”) refers to a structure having two distinct layers of dissimilar material in intimate contact with each other. A superlattice structure is formed by manufacturing a plurality of periodically-repeated heterojunctions one on top of the other in a stacked relationship.

Certain heterostructure materials, such as Aluminum Gallium Nitride (AlGaN) and Gallium Nitride (GaN), create an electron well (i.e., a sheet of electrons) at the interface between the two dissimilar materials resulting from the piezoelectric effect and spontaneous polarization effect therebetween. The resulting sheet of electrons that forms at this interface is typically referred to as a Two-Dimensional Electron Gas (“2DEG”) channel. FETs that operate by generating and controlling the electrons in the 2DEG channel are conventionally referred to as high electron mobility transistors (“HEMTs”).

By stacking a plurality of these two-material heterostructures, and with the addition of appropriate doping in the layers to maintain the presence of the 2DEG channels when stacking a plurality of heterostructure layers, the electron sheets are able to act in parallel, allowing for greater current flow through the superlattice transistor.

When this type of FET is “on”, the superlattice transistor has a lower on-resistance, relative to a single heterostructure-layer transistor, because the multiple 2DEG channels allow a proportionally higher current to flow between the source and drain, resulting in an overall reduction in on-resistance.

Moreover, the transistor of the present disclosure may be capped with a passivating dielectric, such as Si3N4. Castellations/nanoribbons/heterostructures are patterned and etched into the superlattice epitaxial layer of heterostructures. In some cases, etching may be into the buffer beneath, to form the stacked channel structure of the SLCFET that defines a plurality of trenches. The plurality of trenches may have a length, a width, and a depth defining a boundary including a first sidewall surface, a second sidewall surface, and a bottom section located therebetween. The etch damage of the sidewalls and the bottom sections may then be minimized/eliminated through the use of a post-etch clean-up process, such as digital etching of the castellations or heterostructures. For instance, the digital etching may be accomplished through a self-limiting chemical process. In such instances, the chemical process may first expose the etch surfaces to an oxidizer, which forms a thin, self-limiting oxidation on the sidewalls of the plurality of heterostructures followed by a second self-limited chemical process that removes the recently formed self-limiting oxidation. In this way, the etch damage created on the sidewalls and the bottom sections may be removed, leaving behind a more pristine crystalline surface that is ready for further high-quality epitaxial growth. Reintroducing the substrate into the epitaxial growth chamber, a suitable, semiconductor barrier layer, or Schottky barrier layer, is then grown on the sidewalls and the bottom section of at least one of the plurality of trenches. The semiconductor barrier layer, or Schottky barrier layer, may be formed from any practicable material, such as AlGaN or AlN. A Schottky metal layer may then be deposited into at least one of the plurality of trenches to form the gate (such as nickel (Ni) to form the Schottky contact, with gold (Au) on top to create a low resistance gate line). This process along with a process to form a low resistance source and drain contact may result in a Schottky gated SLCFET structure.

Current SLCFET technology uses an insulated gate to separate the gate charge that controls the transistor from the channel charges and minimize gate leakage. However, the reverse bias voltage that may be applied to such a gate is limited due to the electrical stress that creates on the gate dielectric, reducing lifetime and, if high enough, rupturing the gate. The Schottky gate provided herein may be more robust under reverse bias voltage and may sustain much higher electrical fields without failure or degradation. The process provided herein by which a Schottky barrier may be inserted between the stacked channel charges of the SLCFET and the gate charge used to control those charges may act to both increase the power handling capabilities of the SLCFET (through higher achievable gate voltages), while also making the transistor more robust against failure (either induced from effects such as heavy ion radiation and single event effects/single event breakdown/gate rupture or wear out over the transistor's lifetime). As such, the transistor set forth herein introduces a new physical dynamic in the operation of the transistor, permitting higher magnitude reverse bias voltages to be applied on the gate without resulting in the destruction or degradation of the transistor. Additionally, the thickness of this layer is associated with the resulting switching speed capabilities of the transistor. A Schottky contact barrier layer may permit a thinner layer to be used for a given desired applied voltage maximum, allowing both higher power and higher frequency performance simultaneously while these are mutually exclusive when using a gate dielectric.

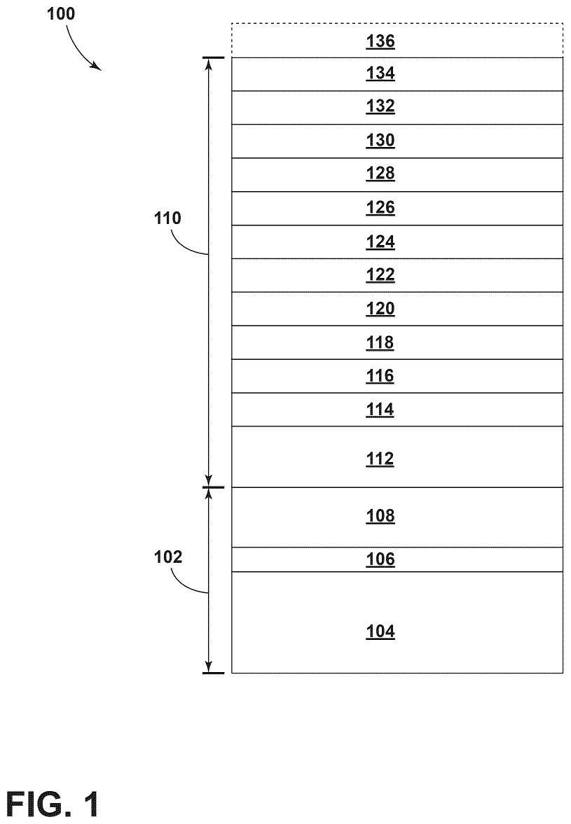

Referring now to the drawings, FIG. 1 illustrates a side view of an epitaxial structure in accordance with various aspects of the present disclosure. As illustrated, the epitaxial structure 100 may include a base structure 102 and a superlattice structure 110. However, the epitaxial structure 100 may include any other component without departing from the teachings provided herein.

In various examples, the base structure 102 may allow the growth, deposit, and/or other formation of the superlattice structure 110 thereon and may be part of a homoepitaxial process (i.e., a base material of the base structure 102 is common with a superlattice material of the superlattice structure 110) and/or a heteroepitaxial process (i.e., the base material of the base structure 102 is varied from the superlattice material the superlattice structure 110 (and, possibly, employing a buffer).

In various cases, the base structure 102 may include a substrate layer 104 (e.g., sapphire), a nucleation layer 106, which may include a combination of a low-temperature GaN layer and a high-temperature GaN layer, and/or a buffer layer 108 based on the material of the superlattice structure 110 to be located thereon. In several examples, the substrate layer 104 may be formed from silicon carbide (SiC). Additionally or alternatively, the nucleation layer 106 may be formed from aluminum nitride (AlN). Additionally or alternatively, the buffer layer 108 may be formed from aluminum gallium nitride (AlGaN). In some instances, the percentage of aluminum in the AlGaN buffer layer may be in the range of between 0% and about 10% as low AlGaN alloys may allow the buffer layer 108 to act both as a buffer layer, as well as an effective back barrier layer to substantially minimize any current leakage from the superlattice structure 110 into the base structure 102 when the transistor is “on”. Each of the substrate layer 104, the nucleation layer 106, and/or the buffer layer 108 may be formed of any other practicable material in various cases.

In several examples, the superlattice structure 110 may include one or more heterostructures. Each heterostructure may include a first layer and a second layer with the second layer being of a dissimilar material to the first layer. In addition, each heterostructure may be designed to create a sheet of electrons (i.e., a 2DEG channel) or a sheet of holes (i.e., a 2DHG channel) at the interface between the two dissimilar materials. In various examples, the heterostructure materials may produce the 2DEG and 2DHG channels at the interface between various materials, including but not limited to Aluminum Gallium Nitride (AlGaN) and Gallium Nitride (GaN), Aluminum Gallium Arsenide (AlGaAs) and Gallium Arsenide (GaAs), Indium Aluminum Nitride (InAlN) and Gallium Nitride (GaN), alloys of Silicon (Si) and Germanium (Ge), and noncentrosymmetric oxides.

In various examples, the superlattice structure 110 may include between 2 and N heterostructures, wherein N is defined as the maximum number of heterostructures that may be grown, deposited, or otherwise formed on each other without cracking or other mechanical failure in the layers or 2DEG channels. As will be appreciated, the value of N is a function of the specific heterostructure materials and thickness of each layer. For example, the superlattice structure 110 is shown in FIG. 1 with six heterostructures. In such an example, layers 112/114, 116/118, 120/122, 124/126, 128/130 and 132/134 include alternating layers of GaN (layers 112, 116, 120, 124, 128 and 132) and AlGaN (layers 114, 118, 122, 126, 130 and 134). Each heterostructure may form a continuous 2DEG channel at the interface within each heterostructure. The specific number of heterostructures within the superlattice structure 110 and the heteromaterials can vary, and the relative positions of AlGaN and GaN may be reversed without departing from the scope of the present disclosure.

In various examples, the percentage of aluminum in the AlGaN layers of the superlattice structure 110 can range from about 0.1 to 100 percent. For instance, the percentage of aluminum in the AlGaN layers of the superlattice structure 110 may be between about 20% and 100% aluminum-content aluminum gallium nitride (Al0.2Ga0.8N and AlN, respectively). Additionally, the AlGaN deposited in layers 114, 118, 122, 126, 130, and 134 may be graded or non-graded. In some instances, one or more AlGaN layers within the superlattice structure 110 may be graded. As used herein, the term “graded” is used to denote the process of gradually changing the percentage of aluminum to its specified percentage, relative to the percentage of gallium.

While the dimensional thickness of layers 112-134 is not critical, in some instances, the thickness of the GaN layer 112 may be at least about 30 nanometers. Additionally, the thickness of the GaN layers 116, 120, 124, 128, and 132 may be between about 1 nanometer and about 50 nanometers. Additionally, the thickness of the AlGaN layers 114, 118, 122, 126, 130, and 134 may be between about 1 nanometer and about 50 nanometers. It will be appreciated that the specific layer thicknesses are a function of the desired epitaxial characteristics.

During the deposition, growth, or another formation process of each of AlGaN layers 114, 118, 122, 126 and 130, a delta doping of an n-type dopant, such as silicon (Si), may be added at the beginning of each AlGaN layer by introducing the dopant gas for a brief time interval, allowing the delta-doping for a confined thickness within the AlGaN layers to induce a 2DEG channel within each heterostructure. Similarly, a p-type dopant, such as magnesium (Mg), may be introduced to induce a 2DHG channel in relevant heterostructures, as applicable.

In a single heterostructure, the dissimilar materials cause an imbalance of stress in the superlattice structure 110, which allows polarization and/or piezoelectric effects to induce carriers to form in a potential well formed by the heterostructure, i.e., to create a 2DxG channel. In a superlattice structure 110 where multiple heterostructures are stacked on top of each other, all heterostructures beneath the top heterostructure may become balanced and carriers that would otherwise induce in those potential wells may not be induced. Adding a doping layer near the interface where the potential well is formed may act to induce the carriers into that potential well, replacing the effect that may have occurred but for the balancing effect of multiple symmetric heterostructures. In several examples, the delta-doping concentration may be between about 1E17 cm³ and about 1E20 cm³. Other delta-doping concentrations may be implemented without departing from the scope of the present disclosure.

In some cases, a layer 136, such as a passivating dielectric, may optionally be located or capped on the top layer of the superlattice structure 110, either as a final passivation layer or as a dielectric for a MISFET (i.e., Metal Insulator Semiconductor Field Effect Transistor). In either case, layer 136 can comprise, for example, a nitride (e.g., SiN, Si₃N₄, and AlN) and/or an oxide (e.g., SiO₂, ZrO₂, HfO₂, and TiO₂). For instance, the layer 136 may be formed from a silicon nitride (Si₃N₄ or SiNx). While the dimensional thickness of the layer 136 is not critical, the layer 136 may be between about 1 nanometer and about 200 nanometers, such as about 10 nanometers.

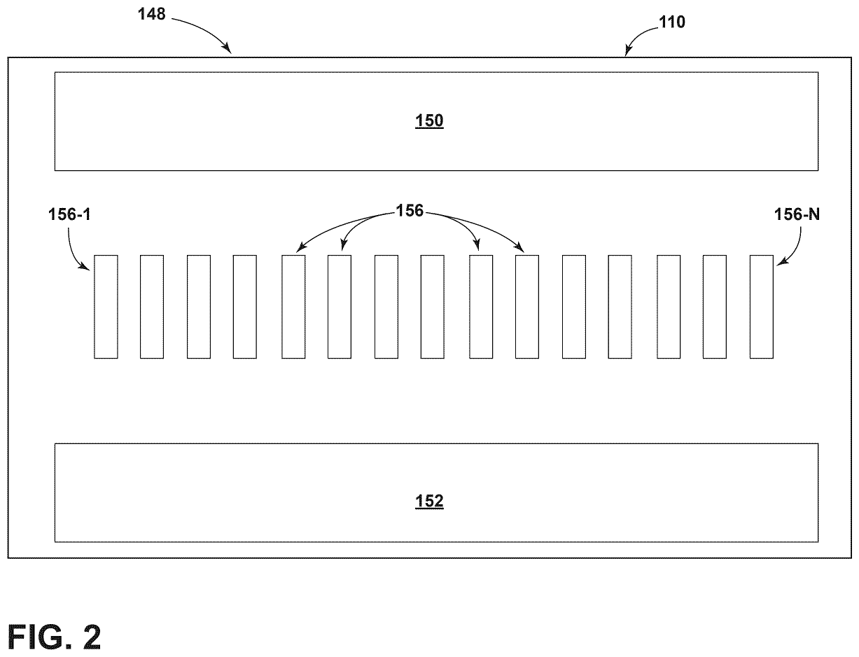

Referring now to FIG. 2, a top view of a normally-on field effect transistor 148 is illustrated in accordance with various aspects of the present disclosure. A normally-on field effect transistor 148 may be designed having a source, drain, and gate deposited upon an epitaxy having a superlattice structure 110. Each heterostructure may contain a 2DEG channel therewithin. In various examples, the transistor 148 may include a source electrode 150 and a drain electrode 152 located on the superlattice structure 110. The transistor 148 can also include one or more trenches 156 etched into the top of superlattice structure 110.

The source electrode 150 and/or the drain electrode 152 may be deposited on the superlattice structure 110 such that the source electrode 150 and/or the drain electrode 152 each have a respective ohmic contact with the superlattice structure 110.

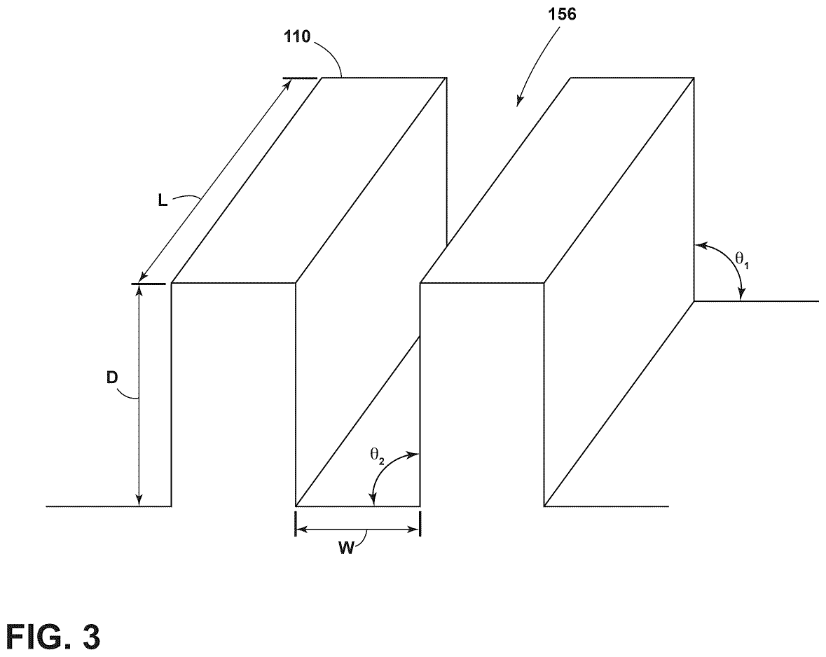

With reference to FIG. 3, an orthogonal view of one of the trenches 156 is illustrated, showing trench dimensions length L, width W, and depth D in accordance with various aspects of the present disclosure. The depth of each trench 156 may be at, or below, the lowest 2DxG channel contained within superlattice structure 110. The length of each trench 156 may be variable and may be as small as 0.01 microns or smaller and as large as the distance between a source electrode 150 and a drain electrode 152. The width of each trench 156 is also variable, and may be 0.01 microns or smaller. Each trench 156 may be formed by removing a portion of superlattice structure 110 from the transistor 148. In various examples, the superlattice structure 110 may be formed with trenches 156 using masks, an etching process, and/or through any other procedure. The number of trenches 156, the length and width of each trench 156, as well as the spacing between each trench 156, may each be a function of the transistor characteristics and the heterostructure materials of the superlattice structure 110. The spacing between each trench 156 (i.e., the unetched portion of superlattice structure 110) may also be a function of the number of trenches 156 to be etched, the width of each trench 156, and the overall width of the transistor 148. In various examples, the dimensions of each trench 156, as well as the spacing therebetween, are the same for all trenches 156. Additionally, the plurality of trenches 156 may be located between the leftmost edges of the source electrode 150 and drain electrode 152 on one end, and the rightmost edges of the source electrode 150 and the drain electrode 152 on the other end.

In several examples, a first angle θ₁ may be defined between one of the sidewalls and a bottom section of the trench 156, and a second angle θ₂ may be defined as the angle between the other sidewall and the bottom section of the trench 156. In various examples, the trench sidewalls are sloped in an obtuse manner, relative to the bottom of the trench 156. In such instances, the first angle θ₁ and the second angle θ₂ may be less than about 110 degrees, such as about 96 to about 98 degrees. However, each of the first angle θ₁ and the second angle θ₂ may be about 90 degrees and/or any other orientation without departing from the scope of the present disclosure.

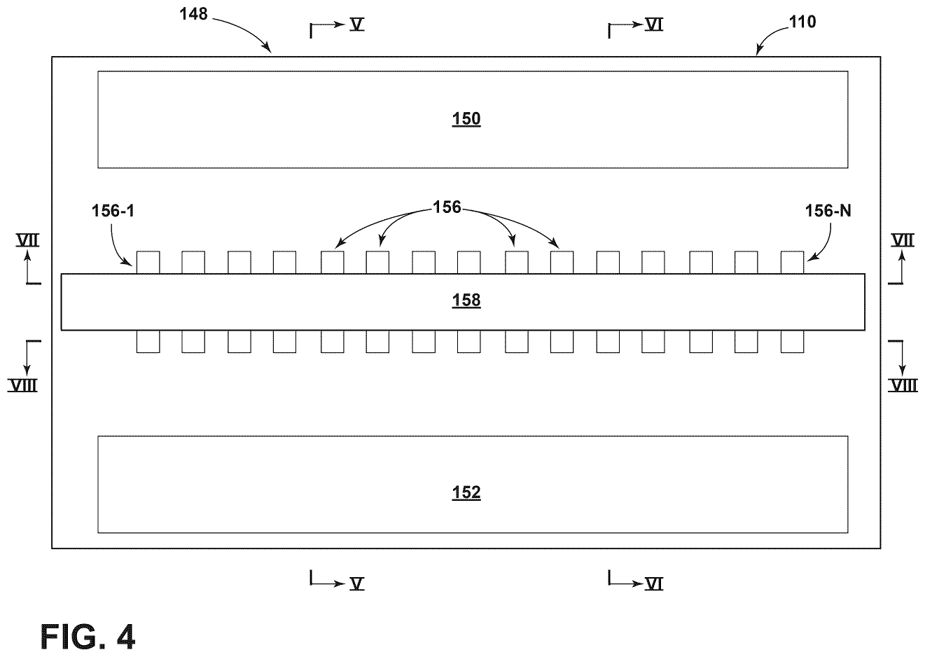

Referring now to FIGS. 4-8, the transistor 148 is illustrated including a gate electrode 158 located on superlattice structure 110 and trenches 156 in accordance with various aspects of the present disclosure. The Schottky gate may include a contact between the anode metal and a single or multiple 2DEG channel layer or layers. Lateral field plates may be added in between the source electrode 150 and the drain electrode 152 to laterally pinch off the multiple 2DEG channels simultaneously, leading to an increased breakdown voltage. A single or multiple lateral field plate(s) may be used to establish an electric field between the anode and the cathode.

In various examples, the length of the gate electrode 158 may be less than, equal to, or greater than the length of trenches 156. As used herein, the “length” is conventionally defined as that dimension perpendicular to the source electrode 150 and the drain electrode 152. Similarly, the “width” is typically defined as that dimension parallel to the source electrode 150 and the drain electrode 152. As shown in FIG. 4, the length of the gate electrode 158 is less than the length of the plurality of trenches 156.

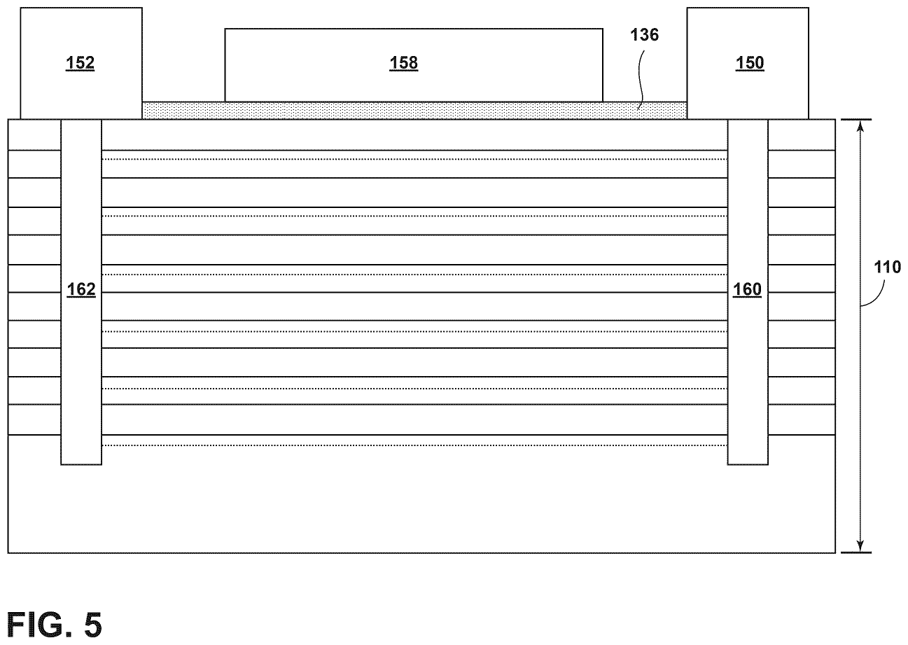

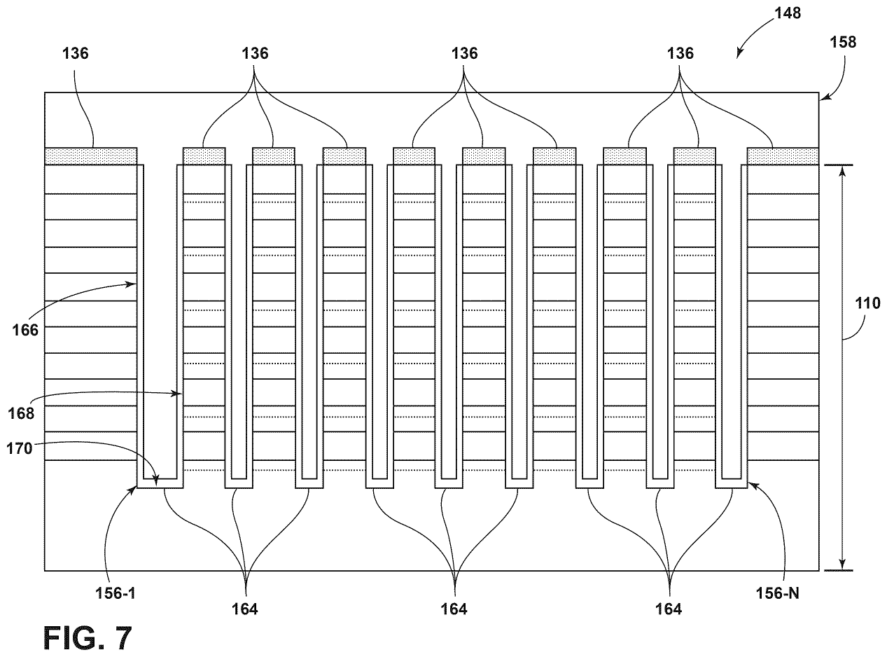

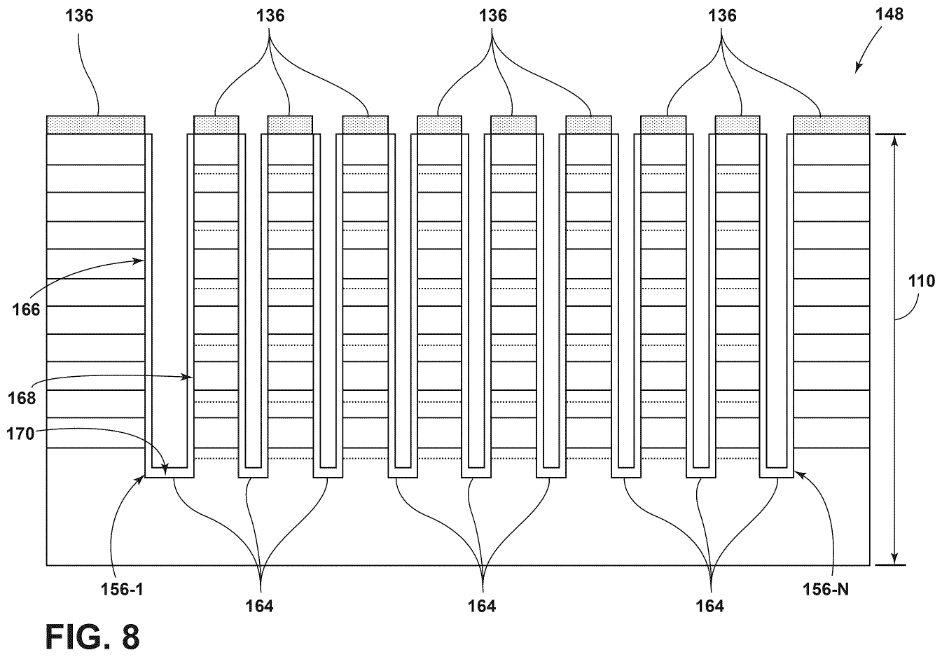

With further reference to FIGS. 5-8, the 2DEG channels within the superlattice structure 110 are shown as dotted lines therewithin, with the source electrode 150 and drain electrode 152 located on the uppermost heterostructure of superlattice structure 110. It is noted that the number of trenches 156 shown in FIGS. 7 and 8 (i.e., 9 trenches 156) is less than the number of trenches 156 shown in FIG. 4 (i.e., 15 trenches 156), which was done to simplify FIGS. 7 and 8. It is to be understood, however, that FIGS. 7 and 8 are to be interpreted as having the same number of trenches 156 as shown in FIG. 4, despite not being depicted in their entirety. To that end, trench 156-1 and trench 156-N are shown in FIGS. 7-8 correspond to the leftmost trench 156 and the rightmost trench 156, respectively, shown in FIG. 4.

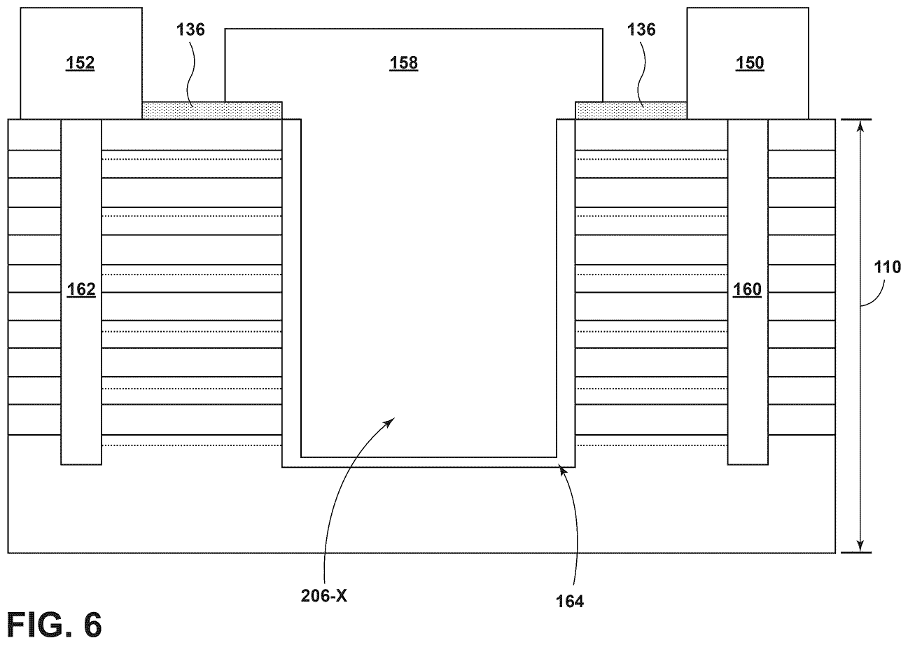

As illustrated in FIGS. 5 and 6, a first via 160 and a second via 162 may be located within superlattice structure 110 under the source electrode 150 and the drain electrode 152, respectively. The first via 160 and the second via 162 may be included to provide low-resistance, ohmic contact between all 2DxG channels and the source electrode 150 and the drain electrode 152, respectively. The first via and/or the second via may be formed by any of the procedures used to form the plurality of trenches 156, such as by etching into the superlattice structure 110.

The length, width, and depth of the first via 160 and the second via 162 may be variable. The length of the first via 160 and the second via 162 may be shorter than the length of the source electrode 150 and/or the drain electrode 152. Moreover, the width of the first via 160 and the second via 162 may be substantially equal to the width of the source electrode 150 and the drain electrode 152, respectively. The depth of the first via 160 and the second via 162 may be below the lowermost 2DEG channel.

In various examples, the first via 160 and the second via 162 may be filled with an X+ regrowth material, the composition thereof being a function of the heteromaterials forming the superlattice structure 110. For a superlattice structure 110 having 2DEG channels, the vias may be filled with an N+ regrowth material, such as Ti or GaN with highly doped silicon therein. Similarly, for a superlattice structure 110 having 2DHG channels, the vias are filled with a P+ regrowth material, such as GaN with highly-doped magnesium therein. In either case, the dopant concentration may be about 1E17 cm³ to about 1E20 cm³, such as about 5E19 cm³.

With further reference to FIG. 6, the depth of each trench 156-x may be located below the lowermost 2DEG channel of the superlattice structure 110. By having a depth of each trench 156-x below the lowermost 2DEG channel of the superlattice structure 110, the bottom section of a gate electrode 158 may also be positioned below the lowermost 2DEG channel of the superlattice structure 110.

Referring further to FIGS. 7 and 8, in some cases, a semiconductor barrier layer 164, or Schottky barrier layer, may be grown or otherwise disposed along the boundary (e.g., along a first sidewall 166, a second sidewall 168, and/or a bottom section 170) of the plurality of trenches 156-x. For instance, the semiconductor barrier layer 164 may be grown in an epitaxial growth chamber after the plurality of trenches 156 are formed in the superlattice structure 110. In various examples, the semiconductor barrier layer 164 may replace a normal gate dielectric and/or introduce a new physical dynamic in the operation of the transistor 148. For example, the semiconductor barrier layer 164 may be a Schottky barrier layer on which a Schottky gate may be formed. In some cases, the semiconductor barrier layer 164 may permit a higher magnitude reverse bias voltage to be applied on the gate without resulting in the destruction or degradation of the transistor 148. The thickness of the semiconductor barrier layer 164 may be associated with the resulting switching speed capabilities of the transistor 148. For instance, the semiconductor barrier layer 164 may permit a thinner layer to be used for a given desired applied voltage maximum when compared to a gate dielectric material, thereby allowing a higher power and/or a higher frequency performance simultaneously while these are mutually exclusive when using a gate dielectric. Additionally or alternatively, the semiconductor barrier layer 164, on which a Schottky gate may be formed, may increase the magnitude of the allowable voltage on the gate. For example, for voltages exceeding 20 volts in magnitude, a source gate may be consistently implemented because power goes as the square of voltage. Or, in other words, doubling the allowable/survivable voltage will quadruple the power handling capability of the SLCFET. As the Schottky gate transistor 148 provided herein may survive three times higher (or more) voltages and/or higher reverse bias voltage levels compared to an insulating gate, it may be anticipated that the resulting transistor 148 will be capable of supporting at least ten times the power of a comparable insulated gate SLCFET.

In various examples, the semiconductor barrier layer 164 may be formed from AlGaN, AlN, and/or any other practicable material that may be deposed, grown, or otherwise formed on at least a portion of the boundary of the plurality of trenches 156. The boundary of the plurality of trenches 156 may include a first sidewall 166 and a second sidewall 168 of the superlattice structure 110 and/or a bottom section 170 that extends between two adjacent sidewalls 166, 168. In various examples, the semiconductor barrier layer 164 may be between about 0.1 nanometers and about 10 nanometers, such as about 0.3 nanometers, about 1 nanometer, about 3 nanometers, about 5 nanometers, about 7 nanometers, or about 10 nanometers. The percentage of aluminum in the semiconductor barrier layer 164 can range from about 0.1 to 100 percent. For example, the percentage of aluminum in the semiconductor barrier layer 164 may be between about 20% and 100% aluminum-content aluminum gallium nitride. The semiconductor barrier layer 164 may be graded or non-graded.

As illustrated, a Schottky deposit may be deposited into the plurality of trenches 156 and patterned to form the Schottky gate. In some cases, the Schottky deposit may include one or more layers. For instance, the Schottky deposit may include a Schottky contact, which may be formed from a material such as Nickel (Ni), and a gate line, which may be formed from a material such as gold (Au) that is deposited at least partially on top of the Schottky contact to create a low resistance gate line.

With reference to FIGS. 4-8, certain sections of the superlattice structure 110 may be devoid of any operable 2DEG channels. For example, the section between the first via 160 and the rightmost edge of the transistor 148, and/or the section between the second via 162 and the leftmost edge of the transistor 148 may be free of any operable 2DEG channels. The term “isolation regions” is defined herein as those sections of the superlattice structure 110 specified hereinabove that are devoid of operable 2DEG channels. Various methods may be used to eliminate and render non-operable those 2DEG channels contained in the isolation regions. For example, an ion-implantation technique may be used whereby helium atoms may be shot at a high velocity into the superlattice structure 110 to disrupt its crystalline geometry, thereby eliminating the 2DEG channels within the targeted region. Additionally or alternatively, a mesa etch may be performed to achieve the same result. Additionally or alternatively, an ion-implantation technique may be performed to create the isolation regions defined above.

Referring still to FIGS. 4-8, having a first and a second isolated implanted region on the left and right sides of the transistor 148 (i.e., the section between leftmost trench 156-1 and the leftmost edge of the transistor 148, and the section between rightmost trench 156-N and the rightmost edge of the transistor 148, respectively) may eliminate the possibility that current will flow between the leftmost portions of the source electrode 150 and the drain electrode 152 on one side, and/or between the rightmost portions of the source electrode 150 and the drain electrode 152 on the other side, which may bypass the plurality of trenches 156.

Similarly, with reference to FIGS. 4-8, having a third and a fourth isolated implanted region in the section between the first via 160 and the rightmost edge of the transistor 148, and/or the section between the second via 162 and the leftmost edge of the transistor 148, respectively, may eliminate the possibility that current will flow around the transistor 148 when multiple transistors are manufactured in close proximity to each other on the same base structure 102.

Given a superlattice structure 110 having a source electrode 150, a drain electrode 152, a plurality of trenches 156, a crenelated gate electrode 158 located within each of the plurality of trenches 156, and all four isolated implanted regions, each as discussed above, the crenelated gate electrode 158 of the present invention can pinch off all current flowing between the source electrode 150 and the drain electrode 152 by application of conventional gate voltages.

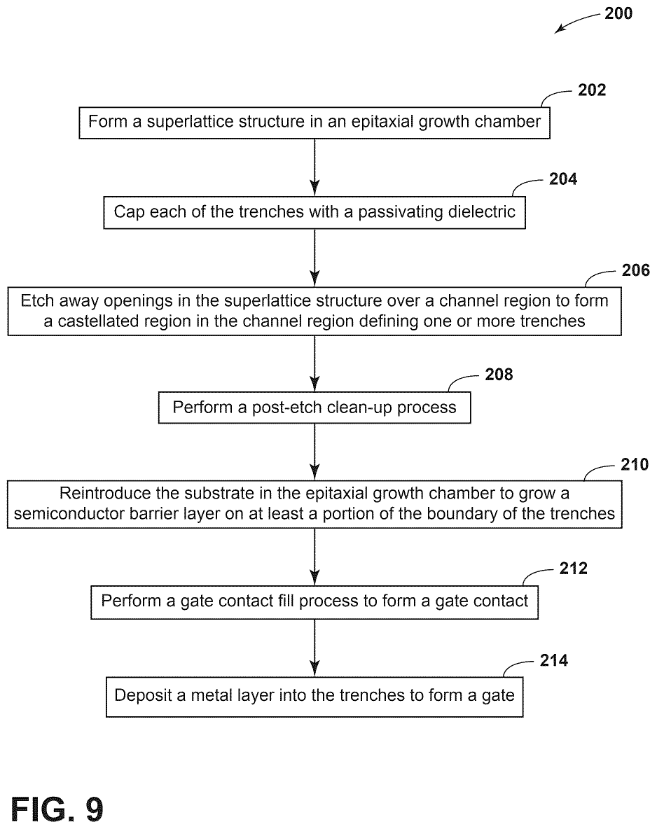

Referring now to FIG. 9, a flow diagram for forming a transistor according to various examples of the present disclosure is illustrated. In general, the method 200 will be described herein with reference to the transistor illustrated in FIGS. 1-8. However, it will be appreciated that the disclosed method 200 may be implemented with devices having any other suitable configurations. In addition, although FIG. 9 depicts steps performed in a particular order for purposes of illustration and discussion, the methods discussed herein are not limited to any particular order or arrangement. One skilled in the art, using the disclosures provided herein, will appreciate that various steps of the methods disclosed herein may be omitted, rearranged, combined, and/or adapted in various ways without deviating from the scope of the present disclosure.

At 202, the method 200 may include forming a superlattice structure in an epitaxial growth chamber. In some examples, the superlattice structure may include a plurality of heterostructures over a base structure by sequentially depositing each layer of the plurality of heterostructures over the base structure with one layer of each heterostructure being doped. Each of the plurality of heterostructures may be grown, deposited, or otherwise formed on each other without cracking or other mechanical failure in the layers or 2DEG channels. Each heterostructure may form a continuous 2DEG channel at the interface within each heterostructure. The specific number of heterostructures within the superlattice structure and the heteromaterials can vary, and the relative positions of AlGaN and GaN may be reversed without departing from the scope of the present disclosure.

At 204, the method 200 may include capping each of the plurality of trenches with a passivating dielectric. In various examples, the passivating dielectric may be laterally spaced from a semiconductor barrier layer. Additionally or alternatively, the passivating dielectric may separate the metal layer from a top portion of one more trenches.

At 206, the method 200 may include etching away openings in the superlattice structure over a channel region to form a castellated region in the channel region defining the one or more trenches. However, it will be appreciated that the plurality of trenches may be formed in any other manner without departing from the scope of the present disclosure. In some examples, each of the plurality of trenches may be etched into the buffer of the base structure to form a stacked channel structure of a SLCFET.

At 208, the method 200 may include performing a post-etch clean-up process before reintroducing the substrate in the epitaxial growth chamber to grow the semiconductor barrier layer. In some cases, performing a post-etch clean-up process further may include digital etching of the plurality of heterostructures. In such instances, the digital etching of the plurality of heterostructures may include exposing the etch surfaces to an oxidizer, to form a self-limiting oxidation on the sidewalls of the plurality of heterostructures, followed by a second self-limited chemical process to remove the self-limiting oxidation on sidewalls of the plurality of heterostructures.

At 210, the method 200 may include reintroducing the substrate in the epitaxial growth chamber to grow a semiconductor barrier layer on at least a portion of the boundary of at least one of the plurality of trenches. The wherein the semiconductor barrier layer may have a width between 1 nanometer and 10 nanometers, and/or any other practicable width. Additionally or alternatively, the semiconductor barrier layer may formed from a practicable material, such as AlGaN or AlN.

At 212, the method 200 may include performing a gate fill process to form a gate. In some instances, the gate may wrap around and substantially surround the top and sides of each of the alternating multichannel heterostructures along at least a portion of its depth and connect each one of the alternating multichannel heterostructures through the non-channel openings.

At 214, the method 200 may include depositing a metal layer into at least one of the plurality of trenches to form a gate. In some instances, the metal layer includes a Schottky contact and a low resistance gate line.

This written description uses examples to disclose the technology to enable any person skilled in the art to practice the technology, including making and using any devices or systems and performing any incorporated methods. The patentable scope of the technology is defined by the claims and may include other examples that occur to those skilled in the art. Such other examples are intended to be within the scope of the claims if they include structural elements that do not differ from the literal language of the claims, or if they include equivalent structural elements with insubstantial differences from the literal language of the claims.

What is claimed is:

1. A field effect transistor comprising:
a base structure;
a first heterostructure having a first layer located over the base structure, a second layer located over the first layer, and a first 2DxG channel located near an interface between the first layer and the second layer;
a second heterostructure having a third layer located in direct contact with the second layer, a fourth layer located over the third layer, and a second 2DxG channel located near an interface between the third layer and the fourth layer;
a source electrode located over the fourth layer and connected to each of the first 2DxG channel and the second 2DxG channel;
a drain electrode located over the fourth layer and connected to each of the first 2DxG channel and the second 2DxG channel;
a plurality of trenches located between the source electrode and the drain electrode, each of the plurality of trenches having a length, a width, and a depth defining a boundary including a first sidewall surface, a second sidewall surface, and a bottom section located therebetween, the bottom section of each of the plurality of trenches being at or below the first 2DxG channel;
a gate electrode located over the fourth layer, the gate electrode located within each of the plurality of trenches; and
a semiconductor barrier layer grown along at least a portion of the boundary of the plurality of trenches between the gate electrode and the first heterostructure and the second heterostructure.

2. The field effect transistor of claim 1, further comprising:
a third heterostructure having a fifth layer located over the fourth layer, a sixth layer located over the fifth layer, and a third 2DxG channel located near an interface between the fifth layer and the sixth layer, wherein the source electrode is located over the sixth layer and connected to each of the first 2DxG channel, the second 2DxG channel, and the third 2DxG channel and the drain electrode is located over the sixth layer and connected to each of the first 2DxG channel, the second 2DxG channel, and the third 2DxG channel.

3. The field effect transistor of claim 1, wherein each of the plurality of trenches is etched into a buffer of the base structure to form a stacked channel structure.

4. The field effect transistor of claim 1, wherein each of the first 2DxG channel and the second 2DxG channel are either 2DEG channels or 2DHG channels, thereby creating a unipolar transistor.

5. The field effect transistor of claim 1, wherein each of the plurality of trenches is capped with a passivating dielectric.

6. The field effect transistor of claim 1, wherein the gate electrode forms a Schottky gate.

7. The field effect transistor of claim 1, wherein the semiconductor barrier layer is grown in an epitaxial growth chamber.

8. The field effect transistor of claim 1, wherein the semiconductor barrier layer extends along at least one of the first sidewall surface, the second sidewall surface, and the bottom section.

9. The field effect transistor of claim 1, wherein the semiconductor barrier layer extends below at least one of the plurality of trenches.

10. The field effect transistor of claim 1, wherein the width of the semiconductor barrier layer is less than 10 nanometers.

11. A method of forming a transistor, the method comprising:
forming a substrate having a superlattice structure and a base structure in an epitaxial growth chamber, the superlattice structure comprising a plurality of heterostructures over a base structure, by sequentially depositing each layer of the plurality of heterostructures over the base structure with one layer of each heterostructure being doped;
etching away openings in the superlattice structure over a channel region to form a castellated region in the channel region defining a plurality of trenches;
reintroducing the substrate in the epitaxial growth chamber to grow a semiconductor barrier layer on at least a portion of a boundary of the plurality of trenches that are respective disposed; and
performing a gate fill process to form a gate that wraps around and substantially surrounds a top and sides of each of the plurality of heterostructures along at least a portion of its depth and connects each one of the plurality of heterostructures through non-channel openings.

12. The method of claim 11, wherein the semiconductor barrier layer has a width between 1 nanometer and 10 nanometers.

13. The method of claim 11, wherein the semiconductor barrier layer is formed from AlGaN or AlN.

14. The method of claim 11, wherein each of the plurality of trenches is etched into a buffer of the base structure to form a stacked channel structure.

15. The method of claim 11, further comprising:
performing a post-etch clean-up process before reintroducing the substrate in the epitaxial growth chamber to grow the semiconductor barrier layer.

16. The method of claim 11, wherein performing a post-etch clean-up process further comprises digital etching of the plurality of heterostructures by exposing etch surfaces to an oxidizer, to form a self-limiting oxidation on sidewalls of the plurality of heterostructures, followed by a second self-limited chemical process to remove the self-limiting oxidation on sidewalls of the plurality of heterostructures.

17. The method of claim 11, further comprising:
depositing a metal layer into at least one of the plurality of trenches to form a gate, wherein the metal layer includes a Schottky contact and a low resistance gate line.

18. The method of claim 17, further comprising:
capping each of the plurality of trenches with a passivating dielectric, wherein the passivating dielectric is laterally spaced from the semiconductor barrier layer and separates the metal layer from a top portion of the plurality of trenches.

19. A field effect transistor comprising:
a base structure;
a plurality of heterostructures positioned on the base structure, the plurality of heterostructures each including a 2DxG channel;
a source electrode located over the plurality of heterostructures and connected to each of the 2DxG channels;
a drain electrode located over the plurality of heterostructures and connected to each of the 2DxG channels;
a plurality of trenches located between the source electrode and the drain electrode, each of the plurality of trenches defining a boundary including a first sidewall surface, a second sidewall surface, and a bottom section located therebetween;
a gate electrode located over the plurality of heterostructures; and
a semiconductor barrier layer grown along at least a portion of the boundary of the plurality of trenches.

20. The field effect transistor of claim 19, wherein the bottom section of each of the plurality of trenches is at or below the first 2DxG channel.
